(19) United States
(12) Patent Application Publication
(10) Pub. No.: US 2012/0041696 A1
(43) Pub. Date: Feb. 16, 2012

(54) Electric Utility Meter To Stimulate Enhanced Functionality

(75) Inventors: H. Britton Sanderford, JR., New Orleans, LA (US); Robert J. Rouquette, Covington, LA (US)

(73) Assignee: SENSUS USA INC., Raleigh, NC (US)

(21) Appl. No.: 13/198,070

(22) Filed: Aug. 4, 2011

Related U.S. Application Data
(60) Provisional application No. 61/372,344, filed on Aug. 10, 2010.

(51) Int. Cl. G06F 19/00; G01R 21/00

(52) U.S. Cl. 702/62; 702/61

(57) ABSTRACT

The present disclosure replaces a standard electric utility meter with a meter having a signal sensor, signal generator, and processor platform to stimulate broad software and firmware development innovation. The utility can then select the ‘application’ that best suits their analysis needs. The meter platform consists of 3 layers: physical interfaces, pre-processing resources, and applications processing & database. The physical interfaces include voltage, current, and load sensors, radio and PLC communications, optical, and power control for advanced outage management. The increased processing capabilities combined with signal and data processing allow for true distributed intelligence in the smart grid. The physical layer, pre-processing DSP and firmware form open APIs for third party developers.

### CROSS-REFERENCE TO RELATED APPLICATION

The present application is based on and claims priority to U.S. Provisional Patent Application Ser. No. 61/372,344 filed Aug. 10, 2010.

### BACKGROUND

The present disclosure generally relates to a method and system for monitoring load characteristics of electric loads in a residential or commercial setting through the use of an electricity meter and identifying the specific types of loads and their respective operating conditions. More specifically, the present disclosure relates to a method and system that monitors the load characteristics of electrical loads and communicates the identification information related to each of the loads to a system operator or a third party for review, analysis and possible direct communication to the owner/operator of the electrical load.

Electric utilities in commercial facilities are interested in monitoring detailed electric power consumption profiles of their customers to analyze the amount of energy being utilized and for monitoring peak load levels and the time of such peaks. Typically, this energy consumption is monitored for the complete residence or commercial facility, since monitoring the energy consumption of each individual appliance contained within the residence or facility typically requires placing a monitoring device on each of the electric loads within the facility. However, acquiring knowledge of the energy consumption of each individual load within the facility would provide additional information for both the owner and the utility in monitoring energy consumption.

In an attempt to monitor energy consumption by each individual electric load within the facility, systems and methods have been developed to track the energy consumption of electric loads within the facility without requiring separate monitoring of each of the loads. One technique to carry out this type of monitoring is referred to as non-intrusive load monitoring. Non-intrusive load monitors (NILM) are devices intended to determine the operating schedule of major electrical loads in a building from measurements made outside of the building. Non-intrusive load monitoring has been known since the 1980's (see Hart U.S. Pat. No. 4,858,141). Non-intrusive load monitoring is generally a process for analyzing the changes in the voltage and currents going into a house and, from these changes, deducing what appliances are used in the house as well as their individual energy consumption. The NILM compares the energy consumption information from the home, such as recorded at an electric meter, and compares the energy consumption information to known load profiles for different types of electrical loads.

Although non-intrusive load monitoring has been known for many years, utilities and other interested parties have been unable to leverage the information obtained from a non-intrusive load monitor.

### SUMMARY

The present disclosure continually runs A/D samples on the load current and the line voltage. The samples occur at >>60 Hz but preferable 4.096 kS/s for harmonic analysis and non-invasive load monitoring (NILM). Additional A/D may be included for PLC at ˜20 kS/s. These samples are stored in a circular buffer, or the like. When an ‘event’—Δ kW, Δ kVAR, outage, under-voltage, over-voltage, or other conditions of interest—occurs, the circular buffer is copied to a capture register along with an appropriate number of post event data samples. This data is either stored to flash or it is post processed to identify certain characteristics as described under the applications set forth below.

Most meters today pre-process voltage and current (V & I) data to extract kWh, kVAR, line frequency, and the like. This information is often presented to other communication processors in a condensed format similar to that which is presented in a utility bill. The prior art communication processors transmit this pre-processed data to the utility. The instant disclosure can perform this same function but in addition, it uses raw sample data presented to an “under the glass” processing means to analyze higher frequency or transient components of the V & I digitized waveforms. The processing means include at least one FFT. The processing means also employs a neural network or other Pattern Recognition correlator to match pre-stored signatures or other criteria to the V & I waveforms. An optional pre-processing means may offload the processing means by running an FFT, decimating digitized samples, and/or pre-qualifying events by a phase change (Δ Ø) or by Δ kW. The load-type templates or criteria are stored in memory and the load templates can be updated via a download via a communications means.

Prior art non-invasive load monitoring, NILM, has typically been performed external to the utility meter. The present disclosure contains the necessary NILM elements within the meter which reduces complexity by eliminating redundant elements, reduces labor since a meter already provides an in-line current sensor, and increases the features and functions possible as discussed herein. The present disclosure can utilize prior art NILM monitoring techniques and systems. The prior art NILM methods can be modified to pattern match/signature match ‘bad actors’/faulty equipment/or inefficient equipment on either the customer side or the utility side.

In addition, by connecting the processing means to communications means, as well as other signal sensing and signal emitter means, a vast suite of energy efficiency, distribution network health applications open-up.

Another feature of the present disclosure is to make partitioned, access protected, program space available to 3rd party developers thus stimulating the market to offer software based innovations.

Another feature of the disclosure is to provide information to a centralized data processor. This processor can warehouse large volumes of data (for example the behavior of a single customer over yearlong seasonal events to predict thermal storage of a residence, and/or it can save the behavior of a million customers as a peak event occurs, or a storm). By combining the power of the processing means in the remote device with the centralized backend processing, data anomalies can be eliminated, better forecasting enabled and inaccuracies from imperfect NILM matching of individual events calculated in the under the glass of the meter. Methods such as Kalman filtering, expert systems, or neural networks can be applied to the backend data.

Another feature of the disclosure is to provide signal sensors and signal generators that are controlled under software and DSP firmware. In this manner firmware can be developed to allow flexible functionality changes, and upgrades as new methods, security procedures and new communications standards are created.

Another feature of the disclosure is to create a universal WAN LAN interface. This interface consists of a down converter section and a phase or frequency discriminator. The phase or frequency is digitized by an A/D and sent to a digital signal processor or the like for further processing into bits and then into protocols. The transmitter section consists of a programmable frequency synthesizer capable of creating nearly any FSK modulation (phase continuous modulation). In addition, a mixer can be used to introduce phase modulations directly, or a mixer can be used to up convert a signal which is created in DSP or the like at a lower frequency or baseband frequency.

By using these methodologies, the WAN LAN can emulate a multiplicity of protocols over a broad range of frequencies. These include 7/13/29/61-ary FSK, 2/4/8/16-ary FSK, BPSK, OQPSK, or broadband FSK modulations, or OFDM. These bit modulations can be further processed to meet MAC/PHY Protocol requirements or standards such as 802.15.4g, or IP stacks such as UDP, TCP or HTTP.

Another feature of the disclosure is to support 3rd party developer innovation and to support multiple simulations applications, which may include the following:
HVAC Fault
iDR Negawatts
Building Energy Management
Bad Actor Detector
Distribution Primary
Office Equipment Status
Transformer Health
Distribution Health
Load Type Identifier
PHEV Load Cycle
Billing, Time Of Use
“Grow Light” Detection
Energy Theft Detection
Locate Stolen Meter
Energy Advisor SW Suite
“Vampire or Phantom” Standby Mode Cost Analyzer
Detect Faulty, Overloaded Breakers
Substation Controller/Relay Logic
Incandescent Load Totalizer (Benefit of Florescent)
Curtailment of Prohibited Load Types During Peak Times

Various other features, objects and advantages of the invention will be made apparent from the following description taken together with the drawings.

### BRIEF DESCRIPTION OF THE DRAWINGS

The drawings illustrate the one mode presently contemplated of carrying out the disclosure. In the drawings:

FIG. 1 is a schematic illustration of the electric meter of the present disclosure;

FIG. 2 is an illustration of the physical configuration of one embodiment of the electric meter;

FIG. 3 is a block diagram illustrating the processing means that forms part of the electric meter of the present disclosure;

FIG. 4 is a block diagram illustrating the operating components of the electric meter of the present disclosure;

FIG. 5 is a block diagram illustrating the electric meter of the present disclosure including various operating components therefor;

FIG. 6 is a schematic illustration of one embodiment of the power supply for the electric meter;

FIG. 7 is an illustration of the various routines and applications that can be carried out by the electric meter of the present disclosure;

FIG. 8 is a flow diagram of one method that can be carried out utilizing the electric meter of the present disclosure;

FIG. 9 is an illustration of the use of the electric meter to sense a downed power line;

FIG. 10 is a flowchart illustrating one type of security that can be utilized with the electric meter of the present disclosure; and

FIG. 11 is a schematic illustration of the communication between multiple electric meters and a data aggregator to determine load types.

### DETAILED DESCRIPTION OF THE INVENTION

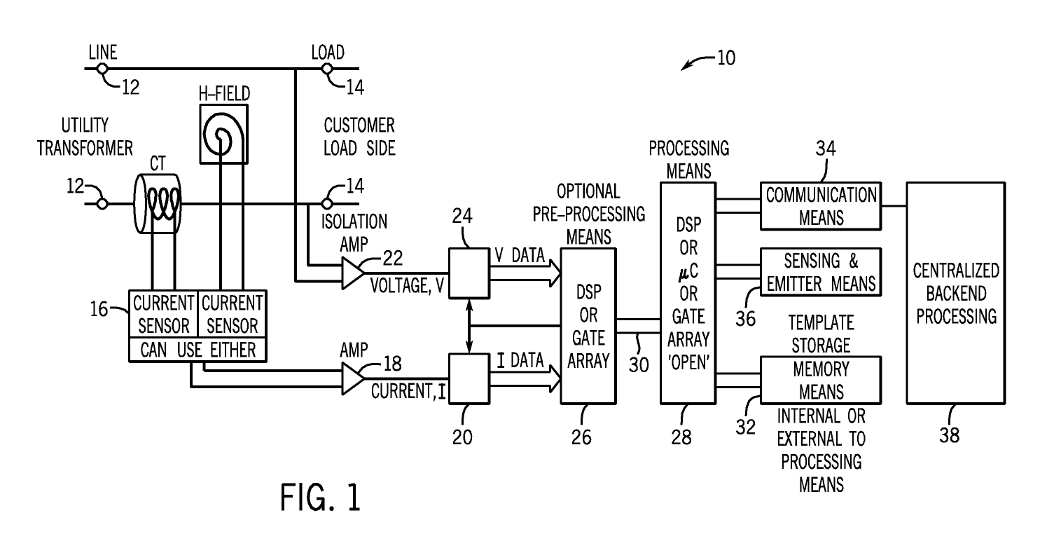

FIG. 1 is a general schematic illustration of an enhanced electric utility meter 10 constructed in accordance with the present disclosure. The electric meter 10 can be used in a home or business environment to monitor the amount of electricity consumed by the residence or business being served through the electric meter 10. The electric meter 10 is positioned between a line connection 12 and a load connection 14 as is typical. The electricity meter includes a current sensor 16 that senses the current being drawn by the load from the line connection. As illustrated in FIG. 1, the current sensor 16 can be one of two different types of current sensors.

The current sensor 16 feeds the sensed current through an amplifier 18 and into an analog-to-digital converter 20. In addition to the current measurement, a voltage signal is sent through another amplifier 22 into a second analog-to-digital converter 24. In the embodiment shown in FIG. 1, the analog-to-digital converter samples the voltage and current at a sample speed. In the embodiment shown, the sample speed is greater than 60 Hz.

The digital signals from the two converters 20, 24 are fed to a pre-processing device 26. The pre-processing device can be used to extract kWH, kVAR, line frequency and other similar information. Such pre-processing is known in many meters today and the information from the pre-processor 26 is typically sent to a utility for billing purposes. In accordance with the present disclosure, the information from the pre-processing device 26 is fed to a processor 28 that is included in the electric meter 10. The processor 28 utilizes the raw sample data presented from the pre-processing device 26 to analyze higher frequency or transient components of the digitized voltage and current waveforms available along communication line 30. As will be described in much greater detail below, the processing means 28 can carry out a variety of different functions and be utilized to provide additional benefits and analysis in accordance with the present disclosure. As one illustrative example, the processing means 28 can compare the voltage and current waveforms to various different templates or criteria stored within a memory device 32 to identify the load type. The memory device 32 can be internal or external to the processor 28 while operating within the scope of the present disclosure. The templates and thresholds contained within the memory device 32 can be uploaded to the electric meter using a communication device 34. The communication device 34 allows for various different information to be obtained from the electric meter 10 or uploaded to the electric meter 10 as desired.

The processing means 28 is further connected to sensing and emitter means 36 that allow the processing means 28 to sense various different physical parameters and emit signals from the electric meter.

In the embodiment shown in FIG. 1, the communication means 34 is connected to a centralized data processor 38. The centralized data processor 38 can warehouse large volumes of data (for example the behavior of a single customer over yearlong seasonal events, or can be used to save the behavior of millions of customers as a peak event occurs, such as a storm). By combining the power of the processing means 28 within the electric meter with the processing at the centralized back end 38, data anomalies can be eliminated, better forecasting enabled inaccuracies from imperfect non-invasive load monitoring matching of individual events calculated in the electric meter. Methods such as Kalman filtering, expert systems, or neural networks can be applied to the back end data by the centralized data processor 38.

In the embodiment shown in FIG. 1, the processing means 28 contained within the electric meter is designed to be available to third party developers to create software-based innovations that can be applied to the electric meter 10. The use of an open format allows third party developers to create applications that can be simply stored onto the processor 28 and utilized by the electric meter 10. The hardware and software platform of the present disclosure includes open API/Device Drivers/interfaces and an open operating system. Such a platform allows for smart metering/smart grid applications for which third party developers can create new software, firmware, DSP and back-end databases and analysis programs and applications. As an illustrative example, set forth below are types of tool kits that could be developed and operated by the processing means 28:
4096 Point FFT, 2 per Sec, 1.0 sec span with 0.5 sec overlap (NILM and Diagnostics)
   Allows for capturing the 29^{th} harmonic. (34^{th} is the highest detectable with this schema)
   Use of a von Hann data taper window strongly recommended
   Only even-frequency bins are kept for NILM use (2 Hz to 2046 Hz)
   4.096 kS/s 16-bit to 24-bit I & V Buffer
   Decimating filter required to use with higher sample rates.
˜20 kS/s, 24-bit I & V (PLC)
   If utilizing same ADCs as 4096 point FFT, sample rate should be an integer
   multiple of 4.096 kS/s to optimize decimating filter performance.
Alternative PLC
   PLC using line voltage in the 35-90 kHz range can support multiple standards including IEC 61334, ERDF G3, and Iberdrola PRIME. This higher frequency range is limited to the secondary side of the transformer which make it ideal for locating neighboring meters. The higher frequency also limits interference with NILM and other diagnostics.
Capture Buffer I & V, +/−20 Sec (NILM and Diagnostics at power fail)
kWh, kVAR, Line Freq (obtained from metrology μC and/or 4096 point FFT output)
Voltage Arc/Corona Recognition (obtained from 4096 point FFT output)
   Transformer, Insulator, Limb
Load & Line Side PLC
Neighbor Meter Discovery PLC
Neighbor Meter kWh Totalized
1 ms Accurate GPS Timestamp
Phase Detection (ABC)
Current Lead/Lag
Transformer Saturation FFT (obtained from 4096 point FFT output)
Library of Load Signatures
Library of Bad Actor Signatures
   Armature Arcing
   Bearing Fail
   Starter Cap Fail
   Bad Contacts
Home Plug PLC Emulator Stack
Echelon PLC Emulator Stack
IEEE 802.15.4 g
ZigBee
SEP 2.0
6 LoPan
FlexNet
IEEE 802.11.b (Wi-Fi)
C12.19 Tables
C12.18 Optical Port
IP Stack: UDP, TCP, HTTP
Elliptic Security
Mesh Routing Logic+Tables+Discovery
Buddy Mode
Status Table of HAN Loads
Appliance ID/STATUS Over Power Line (C&I Meters Detect on All 3 Phases)

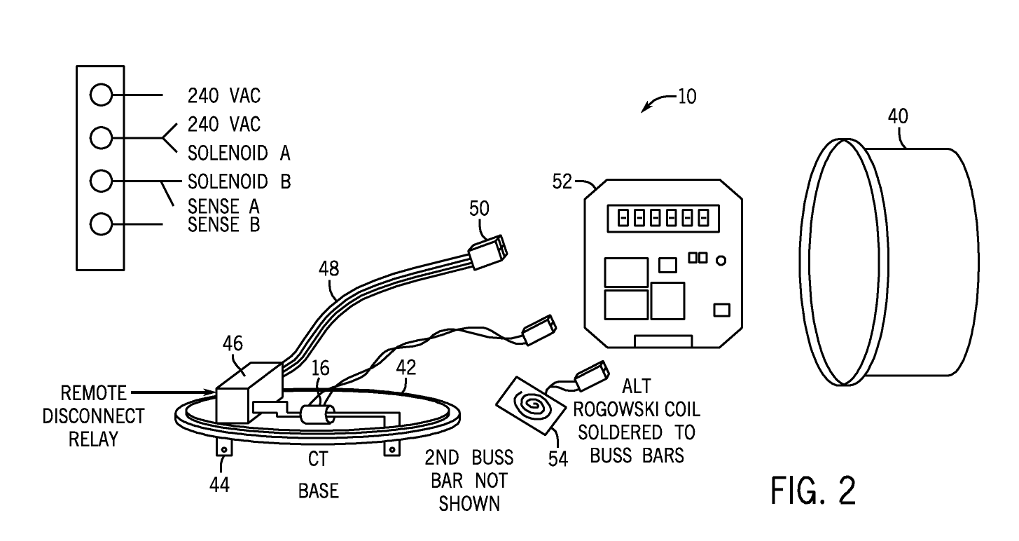

FIG. 2 illustrates the mechanical assembly for the electric meter 10 of the present disclosure. Although one embodiment for the physical configuration of the electric meter 10 is disclosed, it should be understood that the physical configuration of the electric meter could take many different forms while operating within the scope of the present disclosure.

In the embodiment shown in FIG. 2, the electric meter includes a lid 40 that snaps onto a base 42. The base 42 includes a series of blade connectors 44 that allows the meter to be placed into a socket and receive the line voltage. The electric meter includes a remote disconnect relay 46 that allows the entire electricity meter to be disconnected from the line voltage remotely. A series of wires 48 lead from the relay and includes a plug member 50 that connects to circuit board 52. The circuit board 52 includes the operational component for the electric meter that will be described in greater detail below. In the embodiment shown in FIG. 2, the current sensor 16 is coupled to the circuit board 52. An alternative type of current sensor 54 is also shown.

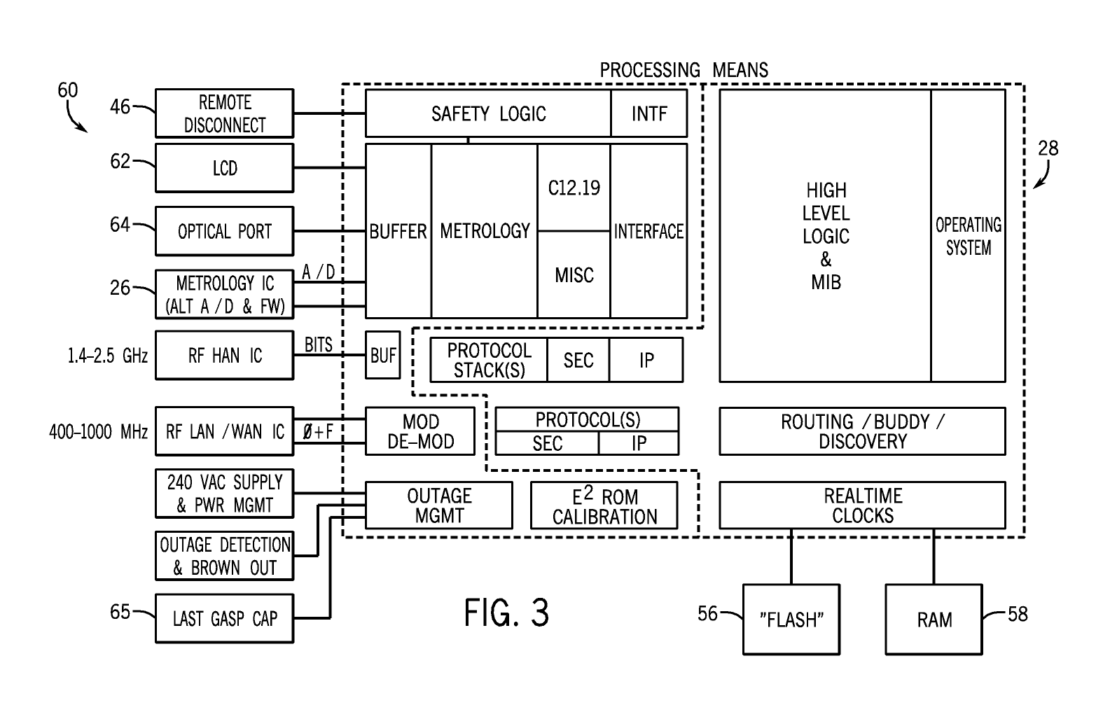

FIG. 3 illustrates one contemplated embodiment for the processing means 28 shown in FIG. 1. As illustrated in FIG. 3, the processing means is connected to both flash memory 56 and RAM 58. The processing means 28 receives and sends signals to a variety of different components 60. As described previously, a remote disconnect 46 is coupled to the processing means 28. An LCD screen 62 allows the processing means 28 to communicate information that can be viewed from external to the meter. An optical port 64 allows for further communication from the processing means 28. The pre-processing means 26 communicates to the processing means 28 as illustrated and previously described in FIG. 1. A backup capacitor 65 provides a source of emergency power upon power loss. The capacitor stores enough energy to power the processor for enough time to share data and send a final transmission. Various other connections are available to the processing means 28 as illustrated in FIG. 3.

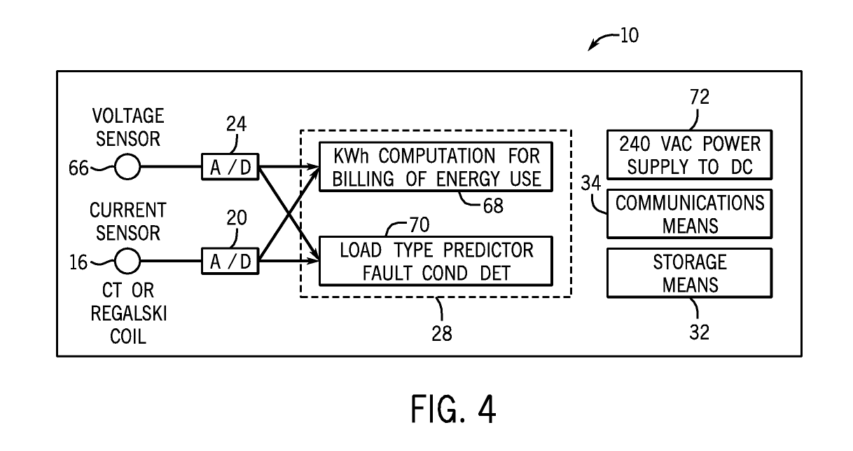

FIG. 4 illustrates yet another depiction of the electric meter 10 of the present disclosure. As previously described in FIG. 1, the electric meter 10 includes a voltage sensor 66 and a current sensor 16 that each feed an analog-to-digital converter 20, 24. The processed voltage and current information from the analog-to-digital converters 20, 24 are fed to the processing means 28 for analysis. In the embodiment shown in FIG. 4, the processing means 28 is used to calculate kilowatt hours as illustrated by box 68. The calculations that take place in box 68 yield a billable quantity that is filtered from various harmonics. The data available for correlation, pattern matching and neural net processing in box 70 is not used for the kWh billing and is thus rich in harmonic content. As previously described, the processing means 28 is contained within the electric meter and thus the calculations occur at the meter itself rather than at an offsite processing location.

As illustrated in FIG. 4, a 240-volt AC power supply 72 is used to provide power to the entire electric meter, including the processing means 28 and the various communication and storage devices. Additionally, a single communication means 34 is used to both report kWh billing information and load-type information. Thus, only a single communication means 34 is required for the two different types of communications.

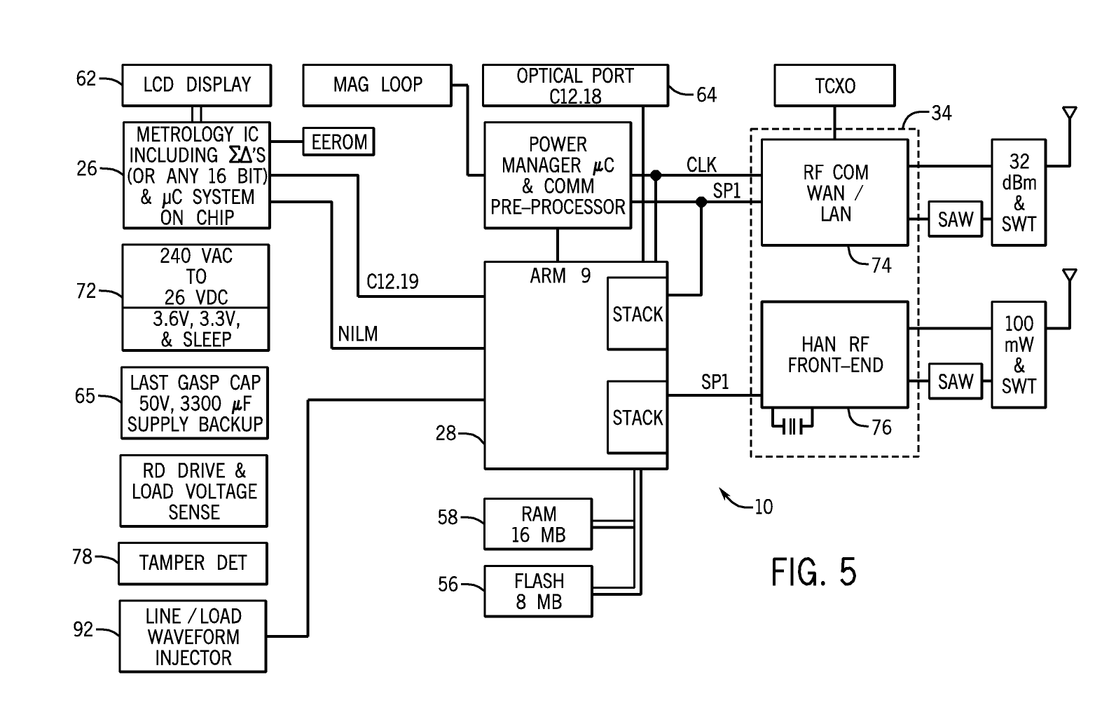

FIG. 5 provides a further, more detailed schematic illustration of the electric meter 10 of the present disclosure. The diagram shown in FIG. 5 includes additional details compared to the schematic illustration of FIG. 1.

As illustrated in FIG. 5, the electric meter 10 includes the processing means 28. The processing means 28 is connected to both the flash memory 56 and the RAM 58. The communication means 34 in the embodiment shown in FIG. 5 includes both an RF communication device 74 that communicates over both WAN and LAN networks. A second device 76 provides another type of communication from the electric meter 10 over a HAN interface. The HAN interface can talk to present and developing endpoints and prevents the utility from making a bad choice of a HAN standard.

As illustrated in FIG. 5, a tamper detection circuit 78 communicates with the processing means to determine if and when the electric meter has been tampered with or removed from the meter socket.

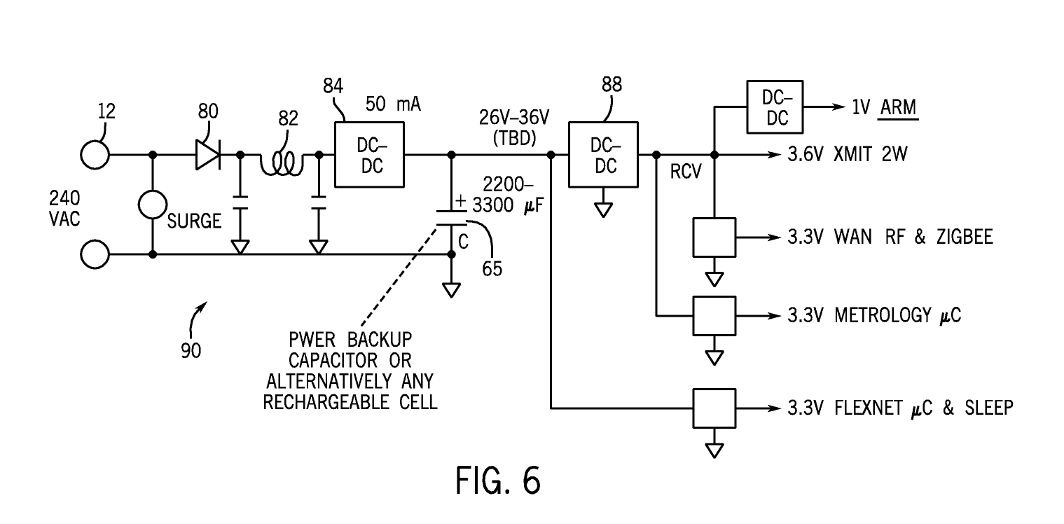

FIG. 6 illustrates one contemplated embodiment for the power supply used to drive the various components of the electric meter. As illustrated in FIG. 6, the power supply from the line 12 is fed through a diode 80 and inductor 82 and into a DC-DC converter 84. A capacitor 65 provides power backup and could be replaced with any type of rechargeable cell. A second DC-DC converter 88 is used to condition the voltage which is then sent to one of a series of regulators as illustrated. The power supply circuit 90 shown in FIG. 6 is meant to illustrate only one possible type of power supply and is not meant to be limiting to the present disclosure.

Referring back to FIG. 5, the electric meter 10 of the present disclosure includes a DSP-based line/lead side signal waveform injector 92. The waveform injector 92 enables multiple applications if a meter can send a tone or an impulse into the customer side or the transformer side and then monitor the reflection. This ability allows the electricity meter to learn something about the load or about the distribution side such as transformer health or that there is an unauthorized tap or short or branch touching the line at 172 feet from the meter or a fuse is arching or there is a ground fault emerging. This feature is especially useful where underground wiring is used.

The injected signal from the injector 92 can be a time-shaped waveform to increase accuracy and to reduce undesirable reflected paths. The injector circuit may be shared with PLC communications. If a PLC signal is generated using digital signal processing, the signal can be universal so that it matches existing and future PLC standards.

When a meter injects a signal on the transformer side that is too high in frequency for the transformer to pass on to feeder systems, only the meters on the transformer side can hear the signal and reply. In this manner, the meter 10 can determine which meters are on the transformer side and analyze such information. As an illustrative example, the knowledge of “neighboring meters” on the transformer can be automatically totalized to determine the difference between daytime and nighttime loads and by using ambient temperature to estimate if the transformer is properly sized.

In one embodiment, the waveform injector can be a power MOSFET in a push pull or Class E configuration. The signal generator is a DSP that can make an arbitrary waveform to produce PLC data signals or a time-of-flight capable shaped waveform. The waveform generator can also vary frequency to measure response peaks and shunts.

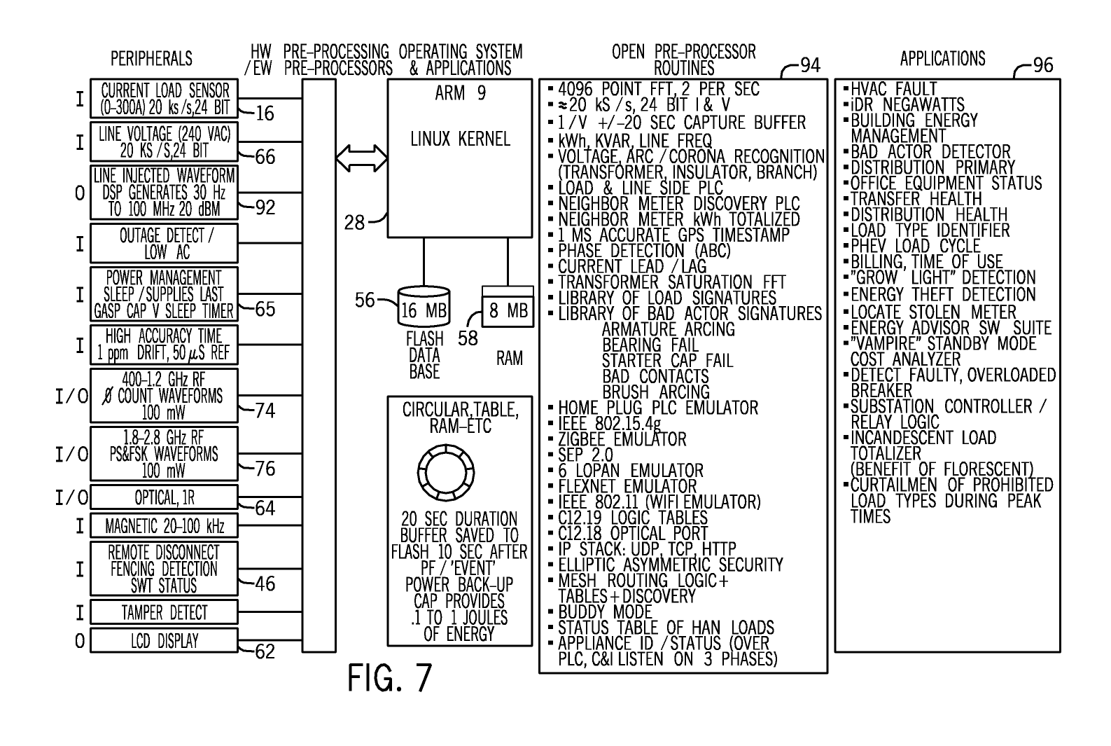

FIG. 7 provides a relatively high-end view of the processing means 10 included in the electric meter. As previously described, the processing means 28 is connected to both flash memory 56 and RAM 58. In the embodiment illustrated, the processing means 28 is an ARM 9 400 megahertz processor that allows the device to support multiple real-time applications. In the embodiment illustrated, the flash memory and RAM are sufficient to allow for the operation of a Linux operating system with partitioned memory. The Linux operating system allows for true open interfaces for third party developers and allows various different types of applications to be developed and uploaded to the processing means 28.

Referring back to FIG. 5, the system includes a universal 2.4 GHz HAN that allows the system to adapt as various different standards evolve. Additionally, the system includes a universal 400-1000 MHz WAN/LAN that allows the system to emulate any type of FSK mesh with a stack download. The two different types of communication devices allow the utility to adjust the communication technique as desired, which reduces the risk in selecting the electric meter. The DFP-based “software radio” allows for vast flexibility.

Referring back to FIG. 7, the system includes the remote disconnect 46 which includes load side voltage sensing and optional arming to enable manual reconnect.

In the diagram of FIG. 7, various different pre-processor routines 94 and applications 96 are set forth and will be described in much greater detail below. As the routines 94 and applications 96 illustrate, the electricity meter can carry out a large number of functions while operating within the scope of the present disclosure. Although various different types of functions and routines are described, it should be understood that the electricity meter of the present disclosure includes onboard processing which allows for an almost unlimited number of applications to be carried out. Further, since the processing means includes the Linux operating system, various different applications can be developed by third parties and uploaded to the electricity meter to continue to enhance the functionality of the electricity meter.

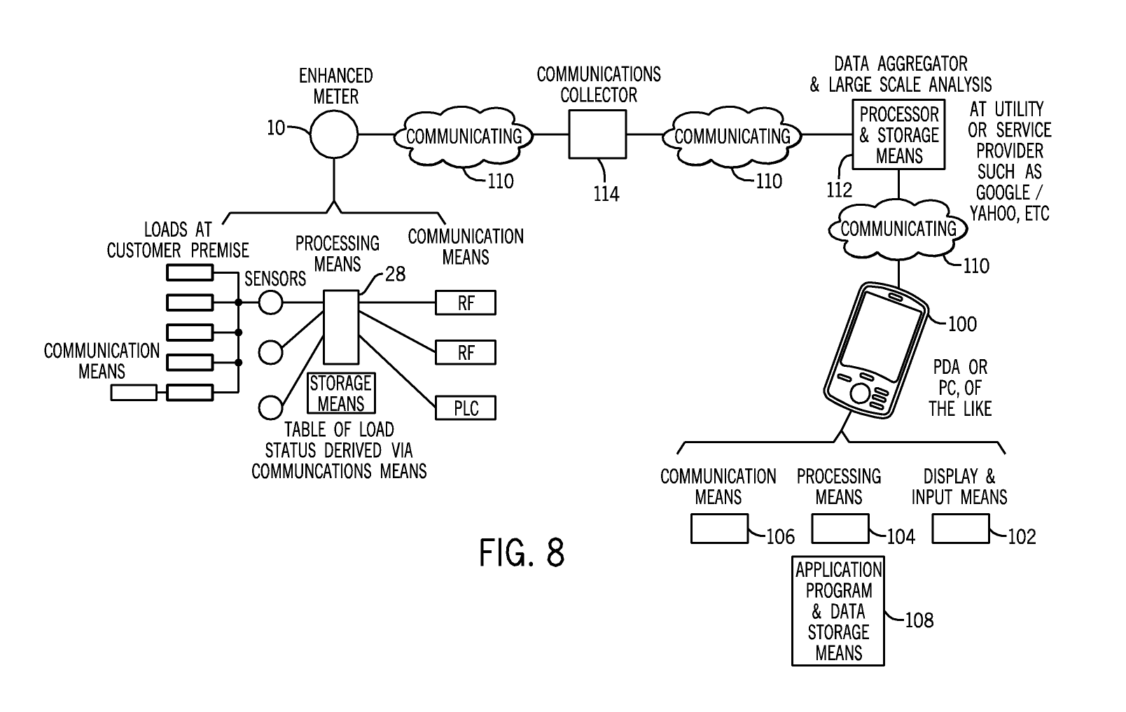

FIG. 8 illustrates one method of utilizing the enhanced electric meter 10 of the present disclosure. Although the embodiment shown in FIG. 8 illustrates one method of utilizing the electric meter 10, it should be understood that various different methods are available while operating within the present disclosure. In the embodiment of FIG. 8, the owner/operator of a customer location can use a computing device 100, such as a PDA, PC or similar device to input parameters into the enhanced meter. In the embodiment illustrated, the computing device 100 includes a display and input means 102, a processing means 104 and a communication means 106. Each of these different components can vary depending upon the specific computing device 100. The computing device 100 can further include an application program and data storage device as illustrated.

In one contemplated embodiment, the program on the computing device 100 can prompt the user to enter various different information, such as the size of the home/building or physical parameters of the building, such as the number of square feet, number of windows, color of the roofing or other related information. Further, the application program 108 can prompt the user to turn on or off an appliance or HVAC system while identifying that appliance in the computing device 100. By turning on and off the device, the electric meter 10 is able to identify load parameters and operating the signatures of the specific device.

The computing device 100 communicates over a network 110 with a processor at a large data aggregator or utility, as illustrated by reference numeral 112. In turn, the processor 112 communicates through the network 110 to a communications collector 114 and ultimately to the electric meter 10.

When the user turns on or off the device as prompted by the program on the computing device 100, the signature of the device is stored within the processor 112. The processing means 28 of the electric meter 10 communicates load signature profiles from the processing means 28 back to the processor 112. Since the processor 112 has learned a signature profile of various devices at the owner/operator location, the processor 112 can identify the type of device turned on or off during normal operations based on the stored load profile. In this manner, the processor 112 is able to “learn” and improve the prediction of the non-invasive load monitoring based upon actual data obtained through the computing device 100.

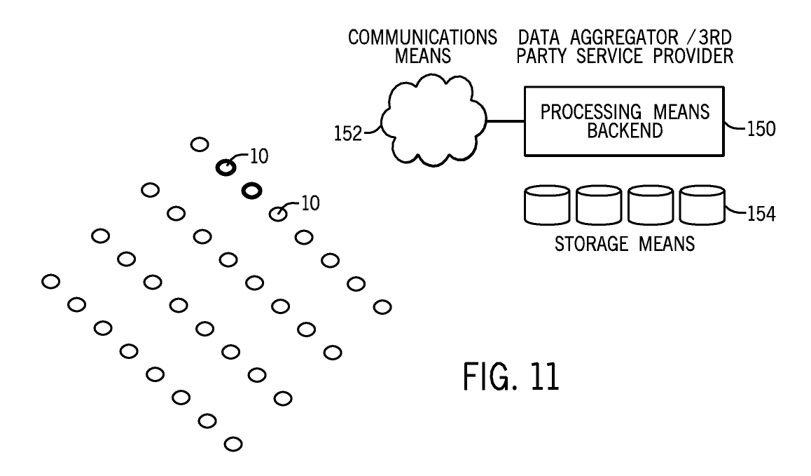

FIG. 11 illustrates the data processing system of the present disclosure in connection with a third party service provider or data aggregator. In the embodiment shown, when any of the plurality of electric meters 10 senses a change in KW (ΔKW), the ΔKW data is captured by the processor on the meter and a load type prediction is made on the meter and time stamped. The load type prediction and data is communicated directly or indirectly to a data aggregator or third party service provider 150 through the communication network 152. The processor at the data aggregator 150 initially pre-processes the data using a Kalman filter to determine whether the change is possible for the type of home at that time of day in that time of year.

If the change is possible, the data aggregator determines whether the change matches with homes of similar characteristics. If yes, back end processing occurs, including enhanced Kalman filtering and Monte Carlos filter as well as neural network methods. The change is then compared to profiles on the storage means 154. This processing improves the device recognition rate from the enhanced meter to a post processed correct recognition rate of >95%.

As set forth above, the electric meter of the present disclosure includes onboard processing means that allow the electric meter to carry out various different functions, features and applications, many of these functions, features and applications are set forth in the diagram of FIG. 7 by reference numeral 96. Several of these applications will now be described in greater detail below.

HVAC Fault

Home and business HVAC operations and maintenance are a large cost to both the homeowner and business owner and represent a large percentage of the total load that a utility must provide. The proper operation and efficiency of the HVAC unit are important to the overall goals of the smart grid. The present disclosure can monitor both voltage and current to detect undesirable operation or fault conditions in HVAC equipment conditions, such as low Freon levels or frozen coils, create a change of load on the compressor and HVAC system which can be detected using comparisons to profiles matching or similar to those conditions. In addition, the duty cycle of the HVAC compressor can also be used to determine how close the system is operating at maximum capacity. Information can be collected from the homeowner or business owner to help improve that prediction including square footage of the building, construction type, building age, roof type, etc.

As discussed above, the electric meter of the present disclosure can detect various different air conditioner faults, such as a low Freon supply, which is detected by increased run time and a gradual decrease in compressor load. Frozen compressor coils can also be detected by increased run time and a decrease in compressor load. If the HVAC system is improperly sized, the electric meter can detect this situation based upon excessive run time for the current temperature level. If the HVAC system has a failed bearing, the electric meter can detect this situation as an increase in reactivity as well as an overall increase in energy consumption. If the HVAC system has a bad starter capacitor, the electric meter can sense this through an increased inductance and possibly an increase in the energy consumed. Further, if the home or business is leaking heat or cold, the electric meter can detect this situation through long-term data aggregation and analysis.

The electricity meter utilizes 4096 .FFT analysis on 16-bit voltage and current samples taken from the electric meter. The changes on the load of the compressor leaves a V/I fingerprint that can be detected by the electric meter. Further, since the electric meter knows the compressor duty cycle and kW draw and outdoor temperature, the electric meter can compare the draws of the home to other homes in the area based upon square footage and the age of the home.

iDR “Nega-Watts”

The concept of “nega-watts” relates to the ability of a utility to shed loads when the amount of power consumption is approaching a peak level. Typically, customers sign up for a power management program and the utility, through remote interrupts, sheds loads at customer sites to reduce the total consumption on the electric grid. In the embodiment of the present disclosure, the electric meter provides the utility database with actual data from many homes over a long period of time, which allows the utility to learn compressor duty cycles and kW draw and outdoor temperatures. By knowing this information, the utility can predict how long a home will allow the devices to remain off until they are overridden and turned back on.

The system of the present disclosure supports knowledge apps that predict the thermal properties of the home or business and thus accurately know how many “nega-watts” of demand response can be delivered before the home or business owner is discomforted and opts-out of the program. Preventing large consumer opt-outs is critical to the sustainability of an energy management program.

Bad Actor Detector

Bad Actors include any equipment which is operating in an undesired manner such as occurs during a bearing failure, starter cap failure, faulty armature arcing in an armature contacts with overly resistive connection and the like. The sensors and processing capabilities in the instant disclosure can be used to make accurate predictions of these cases by matching the outputs of the sensors to templates stored in memory means.

In addition the disclosure can provide sub-cycle power quality measurement and analysis. This may be used to detect and monitor the inrush currents of large loads and the subsequent drop in line voltage caused by the increased current. The drop in line voltage caused by these large loads can often cause other loads to restart or even stall, and this information can be utilized to determine the probable cause and location of customer outages that do not correspond to faults, switchovers, and maintenance events.

Office Equipment Status

Over and above HVAC equipment another significant load in offices and in commercial buildings are various electronic equipment. The instant disclosure can be used to detect conditions on the AC/DC converter and make predictions of load on that equipment type. In addition, servers and other equipment occasionally have predictable scheduled maintenance whereby the On/Off condition of that equipment can be entered into a PC or PDA to improve the instant disclosure's ability to recognize when that load has been turned on or off in the future.

In addition, the ability to recognize PC's, servers, copy machines, fax machines, etc. can be augmented if that equipment is capable of downloading programmable executable code. A program can be introduced onto a PC for example, which causes a PC to enable or disable a device on that PC which crates loan on the electric system, for example, the LCD screen. In addition if any of the office equipment or PCs have access to PLC or to RF communications such as Wi-Fi, those can be used to send a signal to the instant disclosure whereby that information would be used to sense the status of the equipment directly. The disclosure can in addition connect to the customer's WLAN network to search for active IP addresses and identify server infrastructure and other IP based devices. Since the instant disclosure includes the ability to mimic protocols through software based radio and software based PLC this allows the disclosure to adapt to present and future communications methods. These capabilities should prove extremely useful in smaller buildings where customers are most likely to be concerned about multiple small loads.

Transformer Health

Transformer health is an important factor in the future smart grid. Transformers are often sized with a percentage margin predicted for the home or neighborhood. With new innovative products coming on to the market regularly, all of which require power, many of these transformers are mirroring the load limit of their design. Presently, there is no simple or automated way of totalizing the loads that are offered to one of these power pole transformers which would be the summation of typically 4-6 homes.

The present disclosure allows for a tiered method to warn a utility of impending transformer overload or unsafe operating conditions. First it is able to determining the aggregate load presented to the transformer by determining which neighboring meters are also connected to that transformer. It recognizes these neighboring meters by injecting a power line carrier term or message into the transformer side of the meter whereby the other meters similarly attached to this same transformer are able to receive and demodulate that tone. Upon receiving the tone or message, the other meters reply with their _configuration ID_. In this manner, each meter knows the identity of the other meters that share the same transformer. This information can be used between the meters to totalize the total power demanded from the transformer at any point in time. An overloaded condition can be measured against the pre-set limit in the meter and annunciated to the utility the communications means provided on the instant disclosure.

In addition, the meter algorithm can include a pre-set limit that upon exceeding, the individual meters can either vote to disconnect a single meter or to load limit all of the meters such that upon exceeding that load limit level the meter's remote disconnect switch is deactivated. In addition the non-invasive load monitoring means can store a fingerprint matching a power pole transformer with a saturated core. A saturated core represents less of a sinusoidal pattern and more of a deformed triangle wave caused by the addition of a strong third harmonic. Upon the meter or meters detecting such a pattern, they can transmit a warning annunciating system to the utility. In addition, the meters can be set with local control to disable home loads via their internal communications means or they can be programmed to deactivate the remote disconnect switch thus ensuring the transformer is not operated in an overloaded condition. As an illustrative example, if the pole power transformer has a loss of oil, this type of situation creates an arc across the transformer, which can be detected by the electric meter. Likewise, if the core is saturated, it is generated by the transformer and third order harmonics generated, which again can be detected by the electric meter.

Distribution Health (Primary Side of “Pole-Top” Transformer)

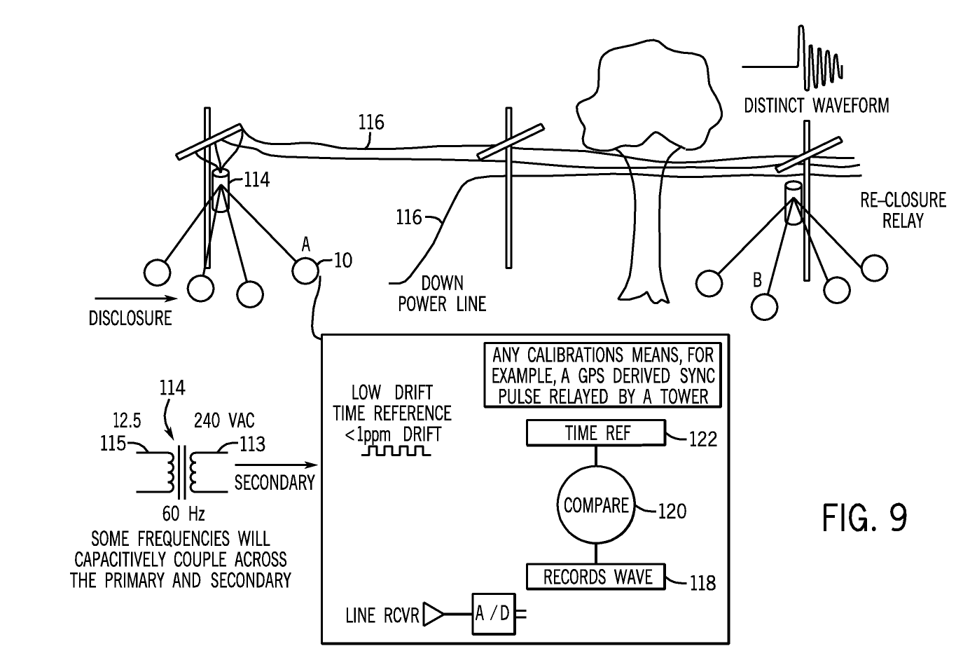

The electric meter 10 of the present disclosure is connected to the secondary 113 of a distribution utility network transformer 114, as shown in FIG. 9. The secondary 113 is coupled through the primary 115 through isolated coils and a transformer core which limits the frequency response of signals that can be conducted through the distribution primary. However, the distribution primary does effect the secondary of the transformer such that multiple meters 10 can be used to sense the effects of the secondary of multiple transforms in order to make a determination or prediction about the condition that exists on the primary side of that transformer. In addition, certain high frequency events like arcing or the effect of an automatic rate closure, creates high frequency components, some of which propagate across the primary to the secondary of the transformer. These can be used, as described herein, to detect certain undesirable conditions that may exist on the distribution primary side. A typical low-pass cutoff frequency for signals coupling between the primary and secondary windings on a distribution transformers is in the 11 kHz to 12 kHz range.

The present disclosure can be used to also monitor undesirable effects on the primary side of the pole top transformer, i.e. the effect of Coronas on a utility pole insulator creates a wideband signal on the primary side, a portion of which will propagate to the secondary side of the transformer. The secondary residual signal energy can be detected using non-invasive load monitoring means in the instant disclosure whereby an appropriate signature is matched to the fault condition. Upon detecting such condition, the meter 10 would use the communications means to annunciate that condition to the electric utility. In addition, Coronas and other effects can be created when a tree branch touches the electric line 116 connected to the primary side of the transformer. Methods as attached in the diagram of FIG. 9 can detect and annunciate those conditions.

As illustrated in FIG. 9, when a power line 116 is down, the transformer 114 creates a distinctive signal that is sensed by any one of the electric meters 10. The electric meter 10 records the distinctive waveform as illustrated by box 118. When the distinct waveform is detected in box 120, the electric meter communicates out to the utility that such a power outage was determined and a time reference label 122 is applied to such communication. In this manner, the electric meter 10 of the present disclosure is able to communicate to the utility of a power outage.

The instant disclosure can also augment outage management procedures by using its ability to recognize neighboring meters that are connected on the same secondary of a pole top transformer. This information can be communicated during a power fail or a power restoral. This information is useful in determining when all loads are restored so that the lineman may move on to repair the next fault condition during a storm. Alternatively, this information can be used to increase the accuracy of the prediction that a power outage situation is not a single home but rather caused by loss of a transformer. This test can be a simple threshold, i.e. if 3 out of 5 of the neighboring meters report a power outage then it is likely that the other 2 are in a power outage condition as well.

Another improvement delivered by the instant disclosure is the ability for it to continually monitor both voltage and current so that when a fault occurs that information is stored to a capture register and either conveyed to a utility or stored to EEROM or Flash memory, such that it can be retrieved for post mortem analysis of the fault condition by the utility at a later time. This sampling can occur at a rate much higher than 60 cycles, i.e. 4.096 kilo-samples per second of both the current and the voltage or this information can be pre-processed such as storage of the magnitudes of each of the 29 harmonics of the fundamental line frequency. Alternatively, other data compression methods can be applied to the stored information.

A key element is the meter's ability to store this fault analysis information both prior to the fault occurring as well as subsequent to the fault occurring. Since most faults result in loss of power this means that the instant disclosure must provide power backup in order to allow 10-20 seconds of recording to occur after the fault condition and where there is no primary power to run the sensor's metrology and A/D converters and processor means. The collection and analysis of the voltage and current waveforms before, during, and after the fault will allow for the approximate location and cause of the fault to be determined.

In addition, the instant disclosure provides accurate time stamping means and highly accurate high stability, load drift temperature compensated crystal oscillator to ensure that the timestamp is accurate and that the time in between samples is highly repeatable. The absolute accuracy of the time stamping is provided in one of several means, one can use interfaces such as 802.11 and software synchronization information communicated over Internet protocols. An alternative method is to use radius signals transmitted from a remote tower that is GPS synchronized of the like. The arrival time of the signal from the tower can be used to timestamp and create an accurate time reference. Even conditions such as the delay of time of flight from a tower to the meter can be calibrated out by knowing the LAT LON of the meter and the LAN LON of the tower and by using the speed of light over the distance the errors there can be readily compensated. So the instant disclosure after a fault condition operates on its internal backup power which is provided through an electrolytic capacitor or the like and 10-20 seconds after the fault event occurs this information is stored off to a capture register including Flash or EEROM and saved until requested by a utility command.

Powered Hybrid Electric Vehicles

The method disclosed herein to determine neighboring meters that share a single utility transformer can be used to also provide benefits for the anticipated increase in powered hybrid electric vehicles (PHEV) utilization. The electric distribution system was not planned for the additional loads created by PHEVs. Typically, a PHEV when charging can create as much load as an entire household in operation, therefore if the 4-6 homes on a single transformer were to each have a powered hybrid electric vehicle connected to a charger at the same time it could double the load on a transform and exceed its capacity. Since the meters know the IDs of their neighbors sharing the same transformer, they can negotiate to allocate time slices for PHEV charging. By assigning timeslots to the PHEVs and by monitoring the accumulated total load on the transformer it can be assured that the maximum numbers of timeslots are allocated for charging and it can be assured that the transformer itself is not operating in an overloaded condition.

In addition, the methods disclosed herein for core saturation detection and arcing can also be used as additional means to ensure proper transformer health when loaded by a PHEV. The instant disclosure can use the RF or PLC communications means to send signals directly to the PHEV to duty cycle charging or they can send a signal to a charging station or they can send a signal to a utility such that the utility can assign charging timeslots to the PHEV or the charging station.

Billing & Tou

The instant disclosure includes the processing necessary to calculate kilowatt hours, peak demand, kVAR, and when that power is utilized. This information can be provided in 1 min, 5 min, 15 min, or hourly intervals. This information is compressed in the instant disclosure and either initiated in transmission by the enhanced electric utility meter or it is provided upon a poll request by the utility backend.

Grow Light Detection

Another feature of the instant disclosure is to be able to detect load type at a customer premise. One of the applications for non-invasive load monitoring is to identify when florescent light ballast are uses in mass. This is a condition that can indicate that florescent lighting is being used for growing illegal plants. This condition can then be annunciated and forwarded to the electric utility.

Energy Theft Detection

Energy can be stolen in a number of ways from an electric utility including taps at the transformer's secondary or primary side. The ability of the instant disclosure to recognize neighboring meters that share a transformer primary is a key benefit in totalizing energy such that “missing energy” can be determined. For example, if a certain amount of energy is provided from a feeder meter to other transformers, a total source energy is known. If the energy that is being utilized at each transformer is then totalized by operating neighborhood meters then the load on that transformer can be known. In addition, the load on every other transformer sharing the same primary side lines can be known. Gaps between the source energy and the energy used can therefore be shown and the approximate location is known between two effected transformers. This allows the utility to both know the quantity of stolen energy, as well as the approximate location and the exact time of the utilization. It also allows the utility to use non-invasive load monitoring to determine signatures of utilization that may be useful at a later time.

Location of a Stolen Meter

If a meter is removed and placed in a drift socket the approximate location of the re-energized meter is known in the following manner:

Upon power restoral the ID of the meter is annunciated to the utility.

The utility can poll that meter and access its information bases including the 4-6 neighborhood meters. Since those neighboring meters have known LAT LON because GIS information is captured during installation, then the approximate location of the stolen meter is known.

Energy Advisor SW Suite

The instant disclosure supports an English language customer help service called the Energy Advisor Suite, the English language messages can be sent via a text message, or email, or an electronic voice targeted at a pre-determined telephone number(s). The advice comes in the form of messages such as “instead of washing clothes at 4:30 pm move your wash time to 8 pm and save $14 per month”. This capability is provided in the instant disclosure via its non-invasive load monitoring such that electable modes such as washer, dryer, dishwasher, or the like, can be detected automatically and the load that they represent in terms of KWh can be calculated and this can be predicted over a pattern of 30 day usage and estimated into impact on the monthly bill. The software either within the instant disclosure under the glass or at the utility backend or at a service provider (such as Google) can additionally know the rate structure of that utility on an hourly basis to determine when a better yet convenient time to operate those appliances. Other sources of advice can include “lower your thermostat temperature by 2 degrees and save $23 per month”.

In addition to suggesting when appliances should be operated, the systems of the disclosure supports knowledge applications that can inform a customer if they have a thermally inefficient home. When the electric meter determines that the home is inefficient, the Energy Advisor Suite suggests possible home improvements that could reduce energy costs, such as adding insulation, replacing windows, etc. Utilities that promote such a program could possibly earn carbon credits.

Incandescent Load Totalizer

Another feature of the Energy Advisor Suite is to notify a homeowner of business owner of the cost of incandescent lights utilized. It can know that the incandescent lights are not being turned off at night. It can also totalize the total load represented by incandescent lights and therefore the approximate monthly bill for their use. It can further calculate the savings if those incandescent lights are replaced by florescent lighting. This information can be further coupled to the sales lead generator or the sales lead auction system.

Time-of-Use Advice Related to ‘Electable Loads’

Another feature of the energy advisor seat identified above is the ability to notify a home owner or business owner of preferred times to operate energy consuming devices. As an example, the energy advisor suite could notify a homeowner that instead of washing clothes at 5:00 p.m., it would be cheaper to wash the clothes at 8:00 p.m. to save approximately $14.00 per month. The ability of the system to generate these kinds of messages is based upon the ability of the system to learn time of use information as well as current energy rates.

“Vampire or Phantom” Standby Mode Cost Analyzer

An increasing amount of power is used by electronic equipment in standby mode. This equipment typically operates AC/DC converters which creates signatures identifiable by the instant disclosure. These devices in standby mode not only create a load directly to operate their optical or RF listening devices to sense whether a remote control is enabled, but they can also create heat which creates an additional load on the HVAC system. One form of advice that the energy advisor provides is to estimate the total cost to the rate payer of operating their various devices in a standby mode. This information goes undetected by home and business owners presently. Without knowledge of this condition or the cost related thereto the customer is unable to make the choice to change their behavior and reduce load from these devices.

Detect Faulty, Overloaded Breakers

A faulty or overloaded breaker can be indicated by increasing resistivity in the contacts of the breaker. This condition can be sensed by using non-invasive load monitoring coupled with signal generation means. Similar to a scattering parameter test set, knowing the injected signal and reflected returns can allow a determination to calculate real and reactive components. Resistivity can be deduced from this information. The interruption of current by a breaker or fuse is detectable via NILM.

Substation Controller/Relay Logic

The instant disclosure is not limited to traditional metering. The sensors communications processing power, database, and operating system make it ideal to provide other high level functions such as substation control, PLC logic, relay logic, or other programmable logic controller functions.

Curtailment of Prohibited Load Types During Peak Times

The instant disclosure can be downloaded with a list of loads which are prohibited during a peak consumption time. Since the NILM can identify what loads are in operation, the disclosure can identify which match the prohibited load table. If a match is found the disclosure can annunciate this condition to the utility, who may impose a higher use tariff, or the disclosure can send a signal (RF or PLC) to a device which controls the power flow to the prohibited device, or the meter can disconnect the “remote disconnect Switch” this disconnects power to that home until the prohibited loads are voluntarily disabled by the homeowner or business.

Other Features of the Disclosure

In addition to the features set forth above, it is contemplated that the electric meter of the present disclosure could be utilized in a system in which the power line is an orthogonal broadcast data channel to help augment security. In such an embodiment, the user can slightly alter the frequency of the 60 Hz where the change in the frequency represents data. The long-term average is 0 Hz. The data represented by the change in frequency can represent timing information and/or a code. If a meter chip is tampered with, it loses the timing or the prior state of the code, thus making tampering with the meter operation or executable software code more difficult. The operation could be much like the key fob security data keys used by large computer centers today, where timing and a code sequence possessed by a user enables the user to access the system. Since the present disclosure listens to the 60 Hz power line and digitizes it and uses DFP methods, any data that a utility applies to the 60 Hz will be readily decodable by the meter. In addition, this method could also be used to prevent attack. If tampering is detected by the utility, the utility can change the code or disable the code on the 60 Hz line. This could, for example, disable the meter's ability to disconnect a load or disable a software code download that was in progress. This system could increase the security level required for transactions that effect a load or it could add challenges before a command could be executed.

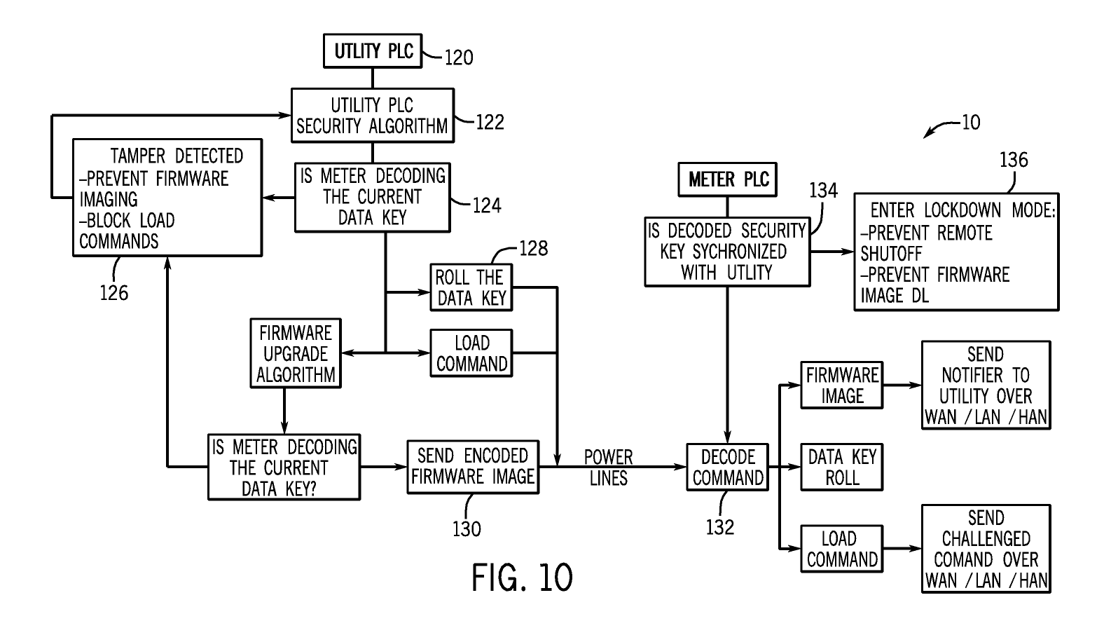

FIG. 10 provides an example of the security system described above. As shown in FIG. 10, a utility PLC 120 implements a PLC algorithm in step 122. The PLC determines whether the meter is decoding the current data key in step 124 if the meter is not decoding the current data key, the utility PLC determines that a tamper has been detected and prevents firmware imaging and blocks load commands.

However, if the meter is decoding the current data key, the system rolls the data key in step 128 and sends an encoded image in step 130.

The meter 10 decodes the command in step 132. If the decoded command is not synchronized with the utility in step 134, the meter enters a lockdown mode in step 136 to prevent remote shutoff and prevent firmware downloads.

This can be used as a secure method for a utility to upgrade the program code in the meter. The utility would broadcast a stream of encoded, encrypted data redundantly to all meters connected to the grid. Even if the data was only sent at 6 Hz, a 64 KB patch to existing code could be downloaded in just one day. A separate, secondary communications could then activate the patch on a meter by meter or by meter group basis.

Mass Secure Meter Reprogramming Over the Power Lines

If all code downloads are implemented over the power line in this manner it will be much more difficult to tamper with a code download then prior art RF methods. A sophisticated software defined digital RF transmitter can emulate an ‘intended” utility download sequence and possibly be made to spoof the physical layer, such that all security defense is in public private key pairs or the like. The means the Spoof code could be inserted in between intended code that was transmitted over the RF protocol.

The instant disclosure presents that such that if the meter is disconnected from the Line side voltage or removed from the socket, any code download sequence is terminated (must start from scratch).

It is far more complex for an attacker to change the frequency of the 60 Hz when a meter is connected to the utility transformer's secondary side. And if the utility detected this activity by monitoring for unauthorized data signals on the 60 Hz line it can readily defeat a successful attack 1) by causing a brief power interruption upstream (which resets the code download per the above paragraph), 2) it can send a competing code, or a 3) a tamper warning code

Since a code download takes one or more days to complete (smallest download allowed is one day) then there is ample opportunity to detect the tamper attempt. When a meter detects the utility is beginning to send a 60 Hz code sequence with download data imbedded upon it, then that meter uses a secondary channel (WAN, LAN, HAN) to communicate a “start of download state”. This can be a full message or a bit set in the normal traffic. This would at the least limit an attack to one household at a time. If an attacker tried to inject a spoof code into the transformer primary or secondary side then multiple meters would send to the utility “I'm being sent a download” and the utility would be alerted, and thus able to use the defenses noted above.

The disclosure also cures another deficiency in the prior art. Almost all smart meters use RF at some point to download code. RF spoof signals can be readily generated and can be sent to many meters at a time. Further, If an attacker can alter the code on a single meter then that meter can be used to propagate the harmful code to yet another meter using the same RF means available in its own HW thus the harmful code can spread in a viral manner. This 60 Hz line method download method is immune to this form of attack which is of the greatest concern to security experts. The instant invention does not possess the HW to alter the frequency of the 60 Hz to inject harmful messages which may be heard by another meter. Thus even if an attack on one meter could be successful the attacker would have to proceed house by house. Since each house takes at least a day, the attack could never get enough scale to harm the operation of the utility and further the utility would have ample time to detect and to locate the attacker. Realize that such attacks cannot come from a clandestine van driving by a neighborhood but must be attached to utility power lines which are in specific locations. By using the methods described herein and taking advantage of the data from a multiplicity of meters, the location of the attacker tap into the 60 Hz could be determined.

Every “N” code segments that are downloaded into temporary memory such as flash can be checked with a CRC or the like and that result can be transmitted back to the utility via another channel (WAN/LAN/HAN) in an encrypted manner so that the utility can verify that the code segments have not been tampered with.

Wireless Meter Programming Security Additions

In addition to the proposed transmission line programming scheme, the RF meter programming can be augmented by incorporating mandatory program download ACKs and an overriding ABORT/LOCKOUT command from the tower that will enable immediate termination of unauthorized meter programming attempts. The ABORT/LOCKOUT command is a broadcast message and is honored by all meters that hear the message, and it is relayed via buddy or mesh mode to meters without direct radio contact from the tower.

ACK & ABORT/LOCKOUT Sequence

1. Meter receives command to begin the programming cycle.

2. Meter transmits an ACK to the tower including the secure signature contained in the programming command.

3. Tower receives ACK and verifies that signature is valid for the current programming cycle.

4. If the signature does not match the current programming cycle or if a programming cycle is not currently in progress that tower will issue an ABORT/LOCKOUT command to terminate the current programming cycle and/or the unauthorized programming attempt. Any further programming attempts will be disabled for a sufficient length of time to identify and resolve the security threat.

5. If the signature correctly matches the current programming cycle, the tower will continue with the program transmission.

We claim:

1. A data processing system for use with an electric utility, comprising:
An electric meter located at a customer premises;
at least one signal sensor positioned to detect energy usage information at the customer premise and relay the information to the data processing device; and
a data processor contained within the electric meter, wherein the data processor is configured to receive the energy usage information from the at least one signal sensor and perform digital signal processing on the energy usage information.

2. The data processing system of claim 1 wherein the signal sensor is a current sensor.

3. The data processing system of claim 2 further comprising a voltage sensor, wherein the data processor performs digital signal processing on both the sensed current and sensed voltage being drawn by electric loads at the premises.

4. The data processing system of claim 3 wherein the data processor determines HVAC faults for an HVAC system fed by the electric meter based upon the digital signal processing.

5. The data processing system of claim 3 wherein the data processor determines the health of a transformer supplying electricity to the premises based upon the digital signal processing.

6. The data processing system of claim 3 wherein the data processor determines the types of loads connected to the electric meter based on the digital signal processing.

7. The data processing system of claim 6 wherein the data processing device includes a stored database of load profiles, wherein the type of load is determined by the data processor based upon a comparison of the voltage and current consumption to the load profile.

8. The data processing system of claim 3 wherein the data processor determines the type of loads and the time of operation of the loads based upon the digital signal processing, wherein the data processor interrupts operation of the selected loads based upon peak usage periods.

9. The data processing system of claim 3 further comprising a communication device contained within the electric meter, wherein the data processing device communicates usage information and analysis information through the same communication device.

10. The data processing system of claim 3 further comprising a waveform injector contained in the electric meter, wherein the waveform injector is operable to transmit a test signal along a power line connected to the electric meter.

11. The data processing system of claim 1 further comprising a memory device coupled to the data processor to store the results of the digital signal processing.

12. The data processing system of claim 1 wherein the data processor includes an open source operating system that supports user uploadable applications.

13. An electric meter positioned between a supply of utility power and one or more energy consuming loads, comprising:
a voltage sensor positioned to sense the real-time voltage draw of the loads;
a current sensor positioned to monitor the real-time current draw of the loads; and
a digital signal processor contained in the meter, wherein the digital signal processor calculates the energy consumption of the loads and processes the voltage and current consumption to analyze the operation of the loads connected to the electric meter.

14. The electric meter of claim 13 further comprising at least one digital converter operable to convert signals from the current and voltage sensors to digital signal.

15. The electric meter of claim 13 further comprising a communication device coupled to the digital signal processor, wherein the communication device transmits both the energy consumption information and the analysis information from the electric meter.

16. A method of analyzing the energy consumption of a facility having a plurality of electric loads, comprising the steps of:
prompting a consumer to activate a load at the facility;
obtaining an actual load profile for the electrical load actuated by the consumer;
storing the obtained load profile for the electrical load;
monitoring the activation of the plurality of loads through an electricity meter;
conveying the consumption information to the processor; and
identifying the electric load being operated at the premises based upon the load profiles obtained from the device.

17. The method of claim 16 wherein the external processor is located at a third party.

18. The method of claim 16 wherein the user is prompted to activate one of the electric loads through a program contained on a computing unit separate from the electric meter.

19. The method of claim 16 wherein the user is prompted to activate each of a plurality of electric loads at the customer premises such that a load profile is generated for each device.
